(19) United States
(12) Patent Application Publication
(10) Pub. No.: US 2026/0231318 A1
(43) Pub. Date: Aug. 6, 2026

(54) Liquid-Cooling Embedded Chip Lid

(71) Applicant: Mikros Technologies LLC, Claremont, NH (US)

(72) Inventors: Drew M. Matter, Hanover, NH (US); Jesse D. McGowan, Alexandria, NH (US); Joseph T. Sullivan, Hanover, NH (US); Joseph Andrew Vivio, Seattle, WA (US)

(73) Assignee: Mikros Technologies LLC, Claremont, NH (US)

(21) Appl. No.: 19/448,222

(22) Filed: Jan. 14, 2026

Related U.S. Application Data
(60) Provisional application No. 63/753,754, filed on Feb. 4, 2025.

(51) Int. Cl. H05K 1/02

(52) U.S. Cl. CPC H05K 1/0203; H05K 2201/064

(57) ABSTRACT

A microprocessor assembly that includes a printed circuit board (PCB), a microprocessor coupled to the PCB, and a manifold coupled to the PCB and at least partially surrounding the microprocessor. The manifold defines one or more channels that are configured to receive fluid flow through at least a portion of the one or more channels to thermally regulate the microprocessor.

### CROSS-REFERENCE TO RELATED APPLICATIONS

This application claims priority to and the benefit of U.S. Provisional Patent Application No. 63/753,754, filed on February 4, 2025, the entire contents of which are incorporated by reference herein for all purposes.

### TECHNICAL FIELD

This disclosure relates to thermal management of electronic components, and more particularly, to cooling systems for microprocessors.

### BACKGROUND

Microprocessors, such as high-performance Central Processing Units (CPUs) and Graphics Processing Units (GPUs), may generate significant heat during operation. Effective heat dissipation may be crucial to maintain optimal performance of a microprocessor and/or to prevent damage to the processor. Conventional cooling solutions for microprocessors may often employ an integrated heat spreader (IHS) that is in contact with the microprocessor, such as via a thermal interface material (TIM), whereby the IHS and the TIM may function as a heat sink to dissipate the heat generated by the microprocessor over a larger area. For example, the microprocessor may be coupled to a printed circuit board (PCB) and the IHS may be disposed over or may otherwise substantially contain the microprocessor such that the microprocessor is located between the PCB and the IHS. The TIM may also be positioned between the microprocessor and the IHS such that heat generated by microprocessor may transfer from the microprocessor into the TIM, and then further into the IHS to thereafter dissipate the heat.

### SUMMARY

In one implementation, a microprocessor assembly is disclosed. The microprocessor assembly includes a printed circuit board (PCB), a microprocessor coupled to the PCB, and a manifold coupled to the PCB and at least partially surrounding the microprocessor. The manifold defines one or more channels configured to receive fluid flow through at least a portion of the one or more channels to thermally regulate the microprocessor.

In some configurations, the manifold may include an inlet port and an outlet port. A fluid may be configured to enter the one or more channels through the inlet port. The fluid may also be configured to exit the one or more channels through the outlet port.

In some configurations, the manifold may define a cavity. The one or more channels may be located within the cavity.

In some configurations, the cavity may be enclosed by the manifold such that the fluid is only able to enter or exit the one or more channels through the inlet port, the outlet port, or both.

In some configurations, the manifold and the PCB may define a void therebetween. The microprocessor may be located within the void.

In some configurations, the microprocessor assembly may also include a thermal interface material. The thermal interface material may be positioned between the microprocessor and the manifold. The thermal interface material may be located in the void.

In some configurations, the microprocessor may be in indirect contact with the manifold via the thermal interface material.

In some configurations, heat generated by the microprocessor may be configured to transfer from the microprocessor to the thermal interface material. The heat may then further transfer from the thermal interface material to the manifold to thermally regulate the microprocessor.

In some configurations, the microprocessor and the manifold may be coupled to a top surface of the PCB.

In some configurations, the one or more channels of the manifold may be winding micro-channels that define a flow path of the fluid flow.

In another implementation, a manifold is disclosed. The manifold is configured to thermally regulate a microprocessor in thermal communication with the manifold. The manifold includes a cavity defined by the manifold and configured to contain the microprocessor. The manifold also includes an inlet port that is configured to regulate fluid flow entering the cavity and an outlet port that is configured to regulate fluid flow exiting the cavity. The manifold further includes one or more channels defined by the manifold and located within the cavity. To thermally regulate the microprocessor, at least a portion of the one or more channels are configured to receive the fluid flow therein.

In some configurations, the manifold may be configured to indirectly contact the microprocessor.

In some configurations, the inlet port and the outlet port may be located along an upper surface of the manifold.

In some configurations, the inlet port and the outlet port may be located on opposing sides of the manifold.

In some configurations, the manifold may be configured to be coupled to a printed circuit board (PCB) via an adhesive. The microprocessor may be located between the manifold and the PCB and contained within a void defined by the manifold and the PCB.

In some configurations, the manifold may be configured to be coupled to a top surface of the PCB via the adhesive.

In another implementation, a microprocessor assembly is disclosed. The microprocessor assembly includes a printed circuit board (PCB), a microprocessor coupled to the PCB, and a manifold coupled to the PCB. The microprocessor defines one or more channels along a surface of the microprocessor. The manifold and the PCB define a void therebetween. The microprocessor is located in the void. The one or more channels are configured to receive fluid flow through at least a portion of the one or more channels to thermally regulate the microprocessor.

In some configurations, the one or more channels may be etched into a top surface of the microprocessor.

In some configurations, a seal may be disposed between the microprocessor and the manifold and located within the void. The seal may be configured to prevent the fluid flow from penetrating a gap between the microprocessor and the manifold.

In some configurations, the one or more channels may be winding micro-channels that define a flow path of the fluid flow.

### BRIEF DESCRIPTION OF THE DRAWINGS

The disclosure is best understood from the following detailed description when read in conjunction with the accompanying drawings. It is emphasized that, according to common practice, the various features of the drawings are not to scale. On the contrary, the dimensions of the various features are arbitrarily expanded or reduced for clarity.

FIG. 1 is a perspective view of a microprocessor assembly in accordance with the present teachings.

FIG. 2 is an exploded perspective view of the microprocessor assembly shown in FIG. 1.

FIG. 3 is cross-section 3-3 of the microprocessor assembly shown in FIG. 1.

FIG. 4 is another example of a cross-sectional view of a microprocessor assembly in accordance with the present teachings.

FIG. 5 is a top-down view of a microprocessor in accordance with the present teachings.

FIG. 6 is a side view of the microprocessor shown in FIG. 5.

FIG. 7 is a cross-sectional view of another example of a microprocessor assembly that includes the microprocessor shown in FIGS. 5 and 6.

FIG. 8 is a cross-sectional view of another example of a microprocessor assembly in accordance with the present teachings.

### DETAILED DESCRIPTION

Reference will now be made in greater detail to embodiments, examples of which are illustrated in the accompanying drawings. Wherever possible, the same reference numerals will be used throughout the drawings and the description to refer to the same or like parts.

As used herein, the terminology “determine” and “identify,” or any variations thereof includes selecting, ascertaining, computing, looking up, receiving, determining, establishing, obtaining, or otherwise identifying or determining in any manner whatsoever using one or more of the devices and methods are shown and described herein.

As used herein, the terminology “example,” “the embodiment,” “implementation,” “aspect,” “feature,” or “element” indicates serving as an example, instance, or illustration. Unless expressly indicated, any example, embodiment, implementation, aspect, feature, or element is independent of each other example, embodiment, implementation, aspect, feature, or element and may be used in combination with any other example, embodiment, implementation, aspect, feature, or element.

As used herein, the terminology “or” is intended to mean an inclusive “or” rather than an exclusive “or.” That is, unless specified otherwise, or clear from context, “X includes A or B” is intended to indicate any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from the context to be directed to a singular form.

As used herein, unless explicitly stated otherwise, any term specified in the singular may include its plural version. For example, “a computer that stores data and runs software,” may include a single computer that stores data and runs software or two computers – a first computer that stores data and a second computer that runs software. Also “a computer that stores data and runs software,” may include multiple computers that together stored data and run software. At least one of the multiple computers stores data, and at least one of the multiple computers runs software.

As used herein, unless explicitly stated otherwise, the term fluid and/or coolant fluid may refer to, but is not limited to, non-conductive (e.g., dielectric) coolant fluids or conductive liquids. For example, the fluid or coolant fluid may be electronics coolant liquids containing perfluorinated compounds (PFCs), water, and/or water-glycol mixes (brines).

Further, for simplicity of explanation, although the figures and descriptions herein may include sequences or series of steps or stages, elements of the methods disclosed herein may occur in various orders or concurrently. Additionally, elements of the methods disclosed herein may occur with other elements not explicitly presented and described herein. Furthermore, not all elements of the methods described herein may be required to implement a method in accordance with this disclosure and claims. Although aspects, features, and elements are described herein in particular combinations, each aspect, feature, or element may be used independently or in various combinations with or without other aspects, features, and elements.

Further, the figures and descriptions provided herein may be simplified to illustrate aspects of the described embodiments that are relevant for a clear understanding of the herein disclosed processes, machines, and/or manufactures, while eliminating for the purpose of clarity other aspects that may be found in typical similar devices, systems, and methods. Those of ordinary skill may thus recognize that other elements and/or steps may be desirable or necessary to implement the devices, systems, and methods described herein. However, because such elements and steps do not facilitate a better understanding of the disclosed embodiments, a discussion of such elements and steps may not be provided herein. However, the present disclosure is deemed to inherently include all such elements, variations, and modifications to the described aspects that would be known to those of ordinary skill in the pertinent art in light of the discussion herein.

Described herein is a microprocessor assembly that is configured to secure and/or communicate with a microprocessor. As described herein, the microprocessor may be any small-scale processor configured to control one or more operations of an electronic device, such as a computer, table, mobile phone, server, other electronic device, or a combination thereof. The teachings herein are not limited to any one type of microprocessor, and the implementations described herein may be utilized with any size microprocessor or processor. For example, the microprocessor herein may be a complex instruction set computer (CISC) processor, reduced instruction set computing (RISC) processor, very long instruction word (VLIW) processor, a general-purpose applications-based processor (e.g., a processor designed for a wide range of tasks), an embedded microprocessor, a microcontroller, a scalar processor, a vector processor (e.g., a graphics processing unit (GPU)), a multi-core processor (e.g., a GPU or a central processing unit (CPU)), a superscalar processor, an application-specific integrated circuits (ASICs) processor, another processor not yet know by modern technology, or a combination thereof. It should also be noted that the above microprocessors are not necessarily mutually exclusive.

As discussed above, the microprocessor assembly may secure and/or communicate with the microprocessor. By way of example, the microprocessor assembly may include a printed circuit board (PCB), whereby the microprocessor is coupled to and in electronic communication with the PCB. Moreover, the microprocessor assembly may be at least partially contained within a manifold of the microprocessor assembly, whereby the manifold may be configured to thermally regulate the microprocessor during operation. For example, the manifold may be in direct and/or indirect contact with the microprocessor such that heat generated by the microprocessor may transfer through the manifold to dissipate the heat and maintain a temperature of the microprocessor.

In the electronics industry, a microprocessor, such as those described above, may be configured to perform any desired functions of an electronic device. For example, the microprocessor may be a computer processor that contains data processing logic and control on a single integrated circuit (IC) or a small number of ICs. In such a case, a scale (e.g., a size, dimensions, etc.) of the microprocessor may be substantially smaller than processors found in electronics in years past. However, there continues to be developments in the electronics industry to even further scale down microprocessors. Moreover, there continues to be developments in the electronics industry to further increase the power density of microprocessors. That is, the computer power of the microprocessor may significantly increase while still maintaining over even decreasing the overall size of the microprocessor. As a result conventional cooling methods, such as bulky heatsinks and/or coolant fans, may be unable to effectively manage the thermal demands of more modern microprocessors. Thus, such modern a microprocessor may overheat or may be otherwise improperly thermally regulated, which may result in damage and/or improper operation of the microprocessor.

As microprocessor capabilities continue to improve and increase in performance, there remains a need to better thermally regulate the microprocessors during manufacturing, testing, operation (e.g., operation within an end-product (e.g., electronic device)), or a combination thereof. For example, as microprocessors become more advanced and more capable, the heat generated by the microprocessors may significantly increase, which if remained uncontrolled, may result in unwanted damage to the microprocessors and/or negatively impact operation of the microprocessors. Such thermal managements issues may thus also result in increased manufacturing and/or operational costs.

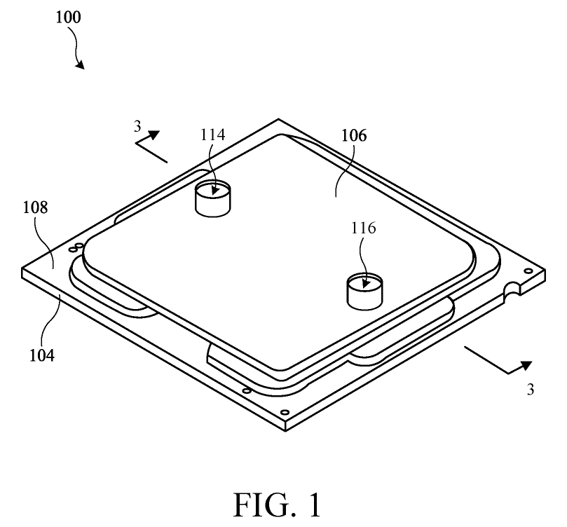

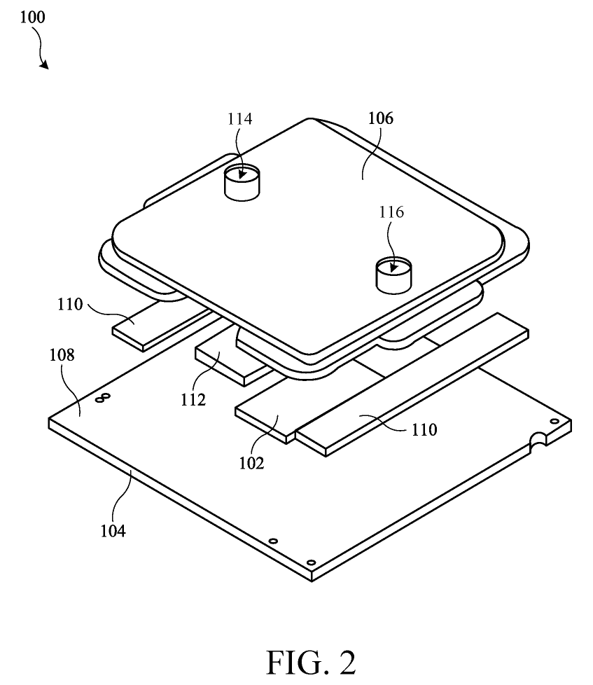

Turning now to the figures, FIG. 1 illustrates a perspective view of a microprocessor assembly 100. FIG. 2 illustrates an exploded perspective view of the microprocessor assembly 100 shown in FIG. 1. The microprocessor assembly 100 described herein may seek to better thermally regulate a microprocessor, such as the microprocessor 102 to prevent damage to the microprocessor 102 that may be caused by unwanted thermal expansion and/or contraction of the microprocessor 102.

The microprocessor assembly 100 may include the microprocessor 102, a printed circuit board (PCB) 104, and a manifold 106. The microprocessor 102 may be coupled to the PCB 104 and/or the manifold 106. By way of example, the microprocessor 102 may be coupled to a top surface 108 of the PCB 104 such that, when the manifold 106 is coupled to the top surface 108 of the PCB 104, the microprocessor 102 is positioned between the PCB 104 and the manifold 106. That is, the manifold 106 and/or the PCB 104 may at least partially contain the microprocessor 102 to protect the microprocessor 102 from unwanted damage that may be caused by moisture, debris, impact, mechanical stress, or a combination thereof. Thus, the manifold 106 may act as a lid that may at least partially enclose the microprocessor 102. As such, for purposes of the disclosure herein, the manifold 106 may also be considered, or referred to as, a lid. Additionally, as discussed further below, the manifold 106 and/or the PCB 104 may at least partially contain the microprocessor 102 to thermally regulate the microprocessor 102 during operation.

The microprocessor 102 may be any of the microprocessors described above. For example, the microprocessor 102 may be a central processing unit (CPU) and/or a graphics processing unit (GPU), but its not limited to any one type of microprocessor for the purposes of the teachings herein. Similarly, the PCB 104 may be any type of PCB. For example, the PCB 104 may contain any desired number of layers, may exhibit any desired flexibility (e.g., rigid, flexible, rigid-flex, etc.), may contain any desired circuity and/or any desired density of circuity, or a combination thereof. Moreover, the microprocessor 102 and the PCB 104 may be configured for any desired application, such as consumer electronics (e.g., smartphones, televisions, laptops, gaming consoles, etc.), industrial applications (e.g., industrial equipment, automation systems, robotics, etc.), automotive applications (e.g., vehicles that require the microprocessor 102 and/or the PCB 104 to withstand harsh environments, such as temperature extremes and/or vibration), medical applications (e.g., medical devices, which may require high reliability and/or biocompatibility), aerospace applications (e.g., aircrafts and/or spacecrafts), server and/or data center applications, high-performance computing applications (e.g., artificial intelligence, machine learning, etc.), other applications, or a combination thereof.

Now turning back to FIGS. 1 and 2, the overall structure of the microprocessor assembly 100 will be discussed in further detail. As shown in FIGS. 1 and 2, the microprocessor 102 may be coupled to the top surface 108 of the PCB 104. The microprocessor 102 may be coupled to the PCB 104 using one or more adhesives, one or more mechanical means (e.g., fasteners, mechanical interlocks, etc.), or a combination thereof. Additionally, the microprocessor 102 may be disposed anywhere along the top surface 108 of the PCB 104, may be at least partially integrated into the top surface 108 of the PCB 104, or both. Moreover, the microprocessor 102 may in some configurations be located along another surface of the PCB 104, such as an opposing bottom surface.

The manifold 106 may also be coupled to the PCB 104. The manifold 106 may be coupled to the PCB 104 in any desired manner, such as via one or more fasteners, one or more mechanical interlocks, or a combination thereof. The manifold 106 may also be coupled to the PCB 104 via an adhesive, such as the adhesive 110. The adhesive 110 may be any suitable adhesive for bonding the manifold 106 to the PCB 104. For example, the adhesive 110 may be a solder (e.g., a solder alloy), an epoxy-based adhesive, a thermally conductive adhesive (e.g., an epoxy-based adhesive that contains conductive particles like silver, graphic, or ceramic fillers), another type of adhesive, or a combination thereof.

In some configurations, the adhesive 110 may also couple the manifold 106 to the PCB 104 to create a seal therebetween. That is, the adhesive 110 may form a seal such the manifold 106 may contain the microprocessor 102 in a sealed environment, thereby facilitating thermal regulation of the microprocessor 102 using a fluid (e.g., a thermal fluid) within the manifold 106 and adjacent to the microprocessor 102. In such a case, the adhesive 110 may be disposed along substantially all or an entirety of the manifold 106 and/or the PCB 104 to establish the seal therebetween. That is, the locations of the adhesive 110 shown in FIG. 1 are for illustrative purposes only, and additional and/or different adhesive locations are envisioned.

The manifold 106 may also at least partially surround the microprocessor 102. For example, the manifold 106 may at least partially define a void when coupled to the PCB 104, and the microprocessor 102 may be located in the void so that the microprocessor 102 is substantially or entirely enclosed by the manifold 106 and/or the PCB 104 (e.g., the top surface 108 of the PCB 104). Based on such a configuration, the manifold 106 may be configured to effectively thermally regulate the microprocessor 102.

For example, the manifold 106 may function as a heat sink to effectively dissipate heat generated by the microprocessor 102 during operation. That is, heat generated by the microprocessor 102 may be transferred to the manifold 106, whereby the manifold may be configured to dissipate such heat to thermally regulate the microprocessor 102. To facilitate such thermal regulation, the manifold 106 may be in indirect contact with the microprocessor 102 (e.g., via one or more components therebetween). By way of example, as shown in FIG. 2, a thermal interface material (TIM) 112 may be disposed between the microprocessor 102 and the manifold 106 such that the microprocessor 102 is in indirect contact with the manifold 106 via the TIM 112.

The TIM 112 may be a thermal paste (e.g., a silicone-based paste that contains thermally conductive fillers, such as zinc oxide, aluminum oxide, or boron nitride), a thermal pad (e.g., a sheet of material, such as silicone with or without added fillers), a liquid metal (e.g., gallium, indium, tin, etc.), a phase change material, a carbon-based material, other materials suitable for cooling the microprocessor 102, or a combination thereof. As such, the TIM 112 may be configured to receive the heat generated by the microprocessor 102 and transfer such heat to the manifold 106 for proper heat dissipation. That is, heat generated by the microprocessor 102 is configured to transfer from the microprocessor 102 to the TIM 112, and then further transfer from the TIM 112 to the manifold 106 to thermally regulate the microprocessor 102.

The manifold 106 may also be configured to thermally regulate the microprocessor 102 by utilizing a coolant fluid (hereinafter referred to as a “fluid”).As discussed above, the fluid may be, a non-conductive (e.g., dielectric) coolant fluid or a conductive liquid. For example, the fluid may be an electronics coolant liquid containing perfluorinated compounds (PFCs), water, and/or water-glycol mixes (brines).

The fluid may be configured to enter the manifold 106 and circulate through at least a portion of the manifold 106 to thermally regulate the microprocessor 102. For example, as shown in FIGS. 1 and 2, the manifold 106 may include an inlet port 114 and an outlet port 116. The inlet port 114 and the outlet port 116 may be in fluid communication with one another. For example, the fluid may be configured to enter the manifold 106 through the inlet port 114, flow through at least a portion of the manifold 106, and exit the manifold 106 through the outlet port 116.

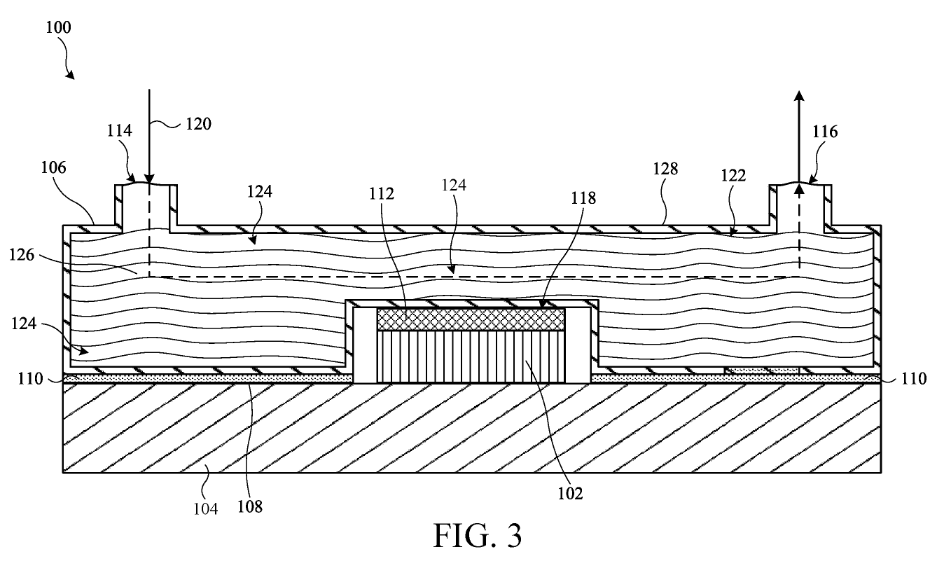

To further illustrate how the manifold 106 thermally regulates the microprocessor 102, FIG. 3 illustrates cross-section 3-3 of the microprocessor assembly 100 shown in FIG. 1. As described above, the microprocessor assembly 100 may include the microprocessor 102, the PCB 104, and the manifold 106, whereby the microprocessor 102 and the manifold 106 may be coupled to the PCB 104, such as along a top surface 108 of the PCB 104.

As shown in FIG. 3, the microprocessor 102 may be coupled to the top surface 108 of the PCB 104 centrally along the PCB 104. The manifold 106 may also be coupled to the top surface 108, such as via the adhesive 110, so that the microprocessor 102 is located between and at least partially contained by the manifold 106 and the PCB 104 (e.g., the top surface 108 of the PCB 104). That is, the manifold 106 may at least partially surround the microprocessor 102 to better thermally manage the microprocessor 102. For example, the manifold 106 and the PCB 104 may define a void 118 therebetween, and the microprocessor 102 may be located within the void 118 such that the microprocessor 102 may be substantially or entirely enclosed by the manifold 106 and/or the PCB 104.

As discussed above, the microprocessor 102 may be in direct and/or indirect contact with the manifold 106. Thus, the microprocessor 102 may be in thermal communication with the manifold 106, directly and/or indirectly. For example, as shown in FIG. 3, the microprocessor 102 may be in thermal communication with the manifold 106 via the TIM 112 located therebetween. That is, the TIM 112 may be positioned between the microprocessor 102 and the manifold 106 such that heat generated by the microprocessor 102 is transferred to through the TIM 112 and into the manifold 106. For example, the TIM 112 may be located in the void 118 along with the microprocessor 102 such that the TIM 112 may directly contact the microprocessor 102.

The manifold 106 may also be configured to thermally manage the microprocessor 102 using a fluid 120 (e.g., a coolant fluid). For example, the manifold 106 may define a cavity 122. The manifold 106 may further define one or more channels 124 that are located in the cavity 122. The fluid 120 may be configured to enter the one or more channels 124, flow through at least a portion of the one or more channels 124 to thermally regulate the microprocessor 102, and exit the one or more channels 124 to dissipate the heat. The cavity 122 may be enclosed by the manifold 106 such that the fluid 120 may only be able to enter or exit the one or more channels 124 through the inlet port 114, the outlet port 116, or both. For example, the fluid 120 may enter the one or more channels 124 through the inlet port 114 and exit the one or more channels 124 through the outlet port 116.

The channels 124 shown in FIG. 3 may have any geometry, cross-section, or shape. Additionally, the manifold 106 may define any number of the channels 124 therein (e.g., within the cavity 122 defined by the manifold 106). The channels 124 may be interconnected such that the fluid 120 may flow through all or a portion of the channels 124. For example, the channels 124 may include or define winding micro-channels, such as those described in U.S. Patent No. 8,474,516, all of which is incorporated herein in its entirety for all purposes. Thus, the manifold 106 may be tuned for any desired manner of thermal regulation of the microprocessor 102. The channels 124 may extend or wind around one or more sides and/or one or more surfaces (e.g., a top surface) of the microprocessor 102 to effectively capture the heat generated by the microprocessor 102.

By way of example, the fluid 120 may flow along a flow path through the channels 124, such as the flow path 126. The fluid 120 may enter the cavity 122 defined by the manifold 106 to flow along and/or through at least a portion of the channels 124. For example, the channels 124 may define one or more openings such that the fluid 120 may flow between the channels 124. Thus, the flow path 126 may be tuned or otherwise optimized to ensure sufficient thermal transfer between the microprocessor 102 and the fluid 120 flowing through the channels 124. For example, the channels 124 may be winding micro-channels such as those described above, and the winding micro-channels may define the flow path 126 of the fluid 120. It should be noted that the flow path 126 is intended to be an illustrative example, and the flow path 126 may be any possible path of the fluid 120 through all or a portion of the channel 124.

To further tune operation of the manifold 106 and the fluid 120 therein, the inlet port 114 and the outlet port 116 may be positioned (e.g., located) anywhere along the manifold 106. The inlet port 114 and the outlet port 116 may be positioned along the same surface. For example, as shown in FIG. 3, the inlet port 114 and the outlet port 116 may be located along and/or at least partially defined by an upper surface 128 of the manifold 106. The inlet port 114 and the outlet port 116 may be integrated into the upper surface 128 of the manifold 106 or may extend (e.g., project) away from the upper surface 128. Thus, the fluid 120 may both enter and exit the manifold 106 through the upper surface 128 of the manifold 106, which may provide a desirable configuration for certain packaging applications of the microprocessor assembly 100.

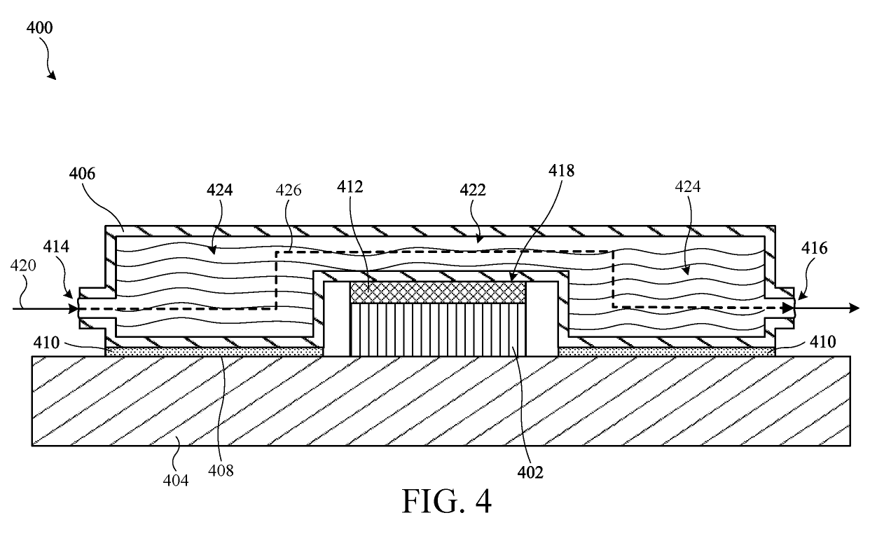

FIG. 4 illustrates another example of a cross-sectional view of a microprocessor assembly 400. The microprocessor assembly 400 may be similar to the microprocessor assembly 100 shown in FIGS. 1-3.

For example, the microprocessor assembly 400 may also include a microprocessor 402, a PCB 404, and a manifold 406. The microprocessor 402 may be disposed on (e.g., coupled to) a top surface 408 of the PCB 404. Similarly, the manifold 406 may be coupled to the top surface 408 of the PCB 404, such as via an adhesive 410. The microprocessor 402, the PCB 404, and the manifold 406 may be similar to the microprocessor 102, the PCB 104, and the manifold 106, respectively, of the microprocessor assembly 100 shown in FIGS. 1-3.

Similar to the manifold 106 of the microprocessor assembly 100, the manifold 406 may be configured to thermally regulate the microprocessor 402. For example, the manifold 406 may be in direct and/or indirect thermal communication with the microprocessor 402. By way of example, the microprocessor 402 may be in indirect communication with the manifold 406 via a thermal interface material (TIM) 412. The TIM 412 may be similar to the TIM 112 of the microprocessor assembly 100. That is, the TIM 412 may be configured to transfer heat generated by the microprocessor 402 from the microprocessor 402 and into the manifold 406 to dissipate the heat. For example, the manifold 406 may be coupled to the top surface 408 of the PCB 404 in a clam-shell manner to define a void 418 located therebetween. The microprocessor 402 and the TIM 412 may be located within the void 418 to substantially or entirely enclose the microprocessor 402 and the TIM 412 between the manifold 406 and the PCB 404.

Also similar to the manifold 106 of the microprocessor assembly 100, the manifold 406 may be configured to thermally regulate the microprocessor 402 via fluid control. That is, the manifold 406 may include an inlet port 414 and an outlet port 416, whereby a fluid 420 may travel through a cavity 422 defined by the manifold 406 between the inlet port 414 and the outlet port 416 (e.g., the inlet port 414 and the outlet port 416 may be in fluid communication). For example, the fluid 420 may enter the cavity 422 through the inlet port 414, travel through the cavity 422 to thermally regulate the microprocessor 402, and exit the cavity 422 through the outlet port 416.

While the microprocessor assembly 100 included the inlet port 114 and the outlet port 116 both located along the upper surface 128 (e.g., a top surface) of the manifold 106, the manifold 406 may provide an alternative or additional configuration. In particular, as opposed to being located along an upper surface of the manifold 406, the inlet port 414 and the outlet port 416 may be located on opposing sides of the manifold 406. Based on the location of the inlet port 414 and the outlet port 416, the fluid 420 may enter the manifold 406 at a first end (e.g., a first side) of the manifold 406 via the inlet port 414, travel through the cavity 422 of the manifold 406, and exit the cavity 422 at an opposing second end (e.g., an opposing second side and/or an opposing second surface) of the manifold 406 via the outlet port 416.

It should also be noted that while the inlet port 414 and the outlet port 416 are located on opposing sides of the manifold 406, the manifold 406 may be scaled (e.g., sized) such that an entirety of the manifold 406 is contained within a perimeter of the PCB 404. That is, an outer perimeter of the manifold 406 may not extend beyond an outer perimeter of the PCB 404 defined be an outer edge of the PCB 404.

To more effectively thermally regulate the microprocessor 402, the manifold 406 may define one or more channels 424. The channels 424 may be located within the cavity 422 of the manifold 406 and may at least partially define a flow path 426 of the fluid 420 through the cavity 422 of the manifold 406. For example, the channels 424 may be winding micro-channels, which may be similar to the channels 124 of the manifold 106 described above. Based on the configuration of the channels 424, the fluid 420 may travel along the flow path 426 adjacent to the microprocessor 402 to transfer heat generated by the microprocessor 402 into the fluid 420 and out of the cavity 422. By way of example, the fluid 420 may enter the cavity 422 through the inlet port 414, flow along the flow path 426 through at least a portion of the channels 424 located within the cavity 422 to thermally regulate the microprocessor 402, and exit the cavity 422 – and thus the manifold 406 – through the outlet port 416 to thereby transfer the heat generated by the microprocessor 402 out of the manifold 406.

The inlet port 414 may regulate the fluid 420 entering the cavity 422. Similarly, the outlet port 416 may regulate the fluid 420 exiting the cavity 422. The inlet port 414 and/or the outlet port 416 may be in communication with a valve, restrictor, regulator, or other implementation that may control a flow rate of the fluid 420 entering the inlet port 414 and/or exiting the outlet port 416. For example, a valve, restrictor, regulator, or other implementation may be upstream of the inlet port 414 (e.g., external to the manifold 406 and in fluid communication with the inlet port 414) to control the flow rate of the fluid 420 entering the inlet port 414.

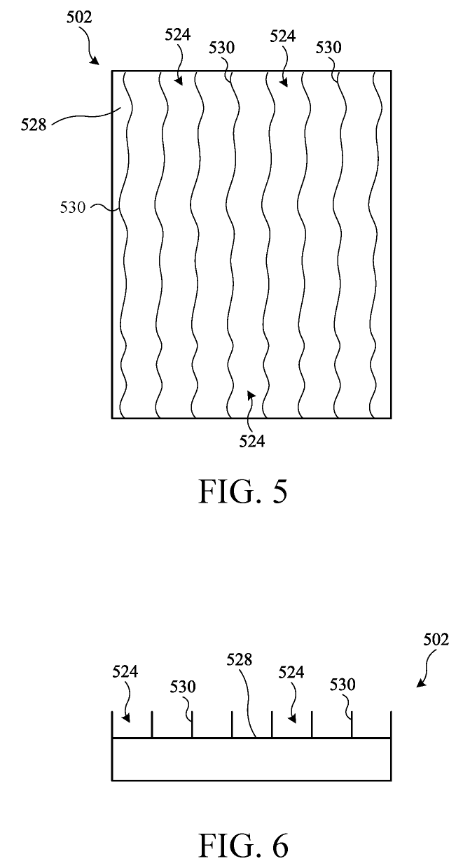

FIG. 5 illustrates a top-down view of a microprocessor 502. FIG. 6 illustrates a side view of the microprocessor 502 shown in FIG. 5. The microprocessor 502 may be similar to the microprocessor 102 and/or the microprocessor 402 discussed above. For example, the microprocessor 502 may be integrated into the microprocessor assembly 100 and/or the microprocessor assembly 400. The microprocessor 502 may be any type of microprocessor, such as those described above. For example, the microprocessor 502 may be a CPU, a GPU, another type of microprocessor, or a combination thereof. It is envisioned that the microprocessor assemblies described herein (e.g., the microprocessor assembly 100, the microprocessor assembly 400, or the microprocessor assembly 700 described below) may be implemented with the microprocessor 502 to thermally regulate the microprocessor 502.

While the manifold 106 of the microprocessor assembly 100 and the manifold 406 of the microprocessor assembly 400 may define one or more channels (e.g., the channels 124 and the channels 424, respectively) within a cavity (e.g., the cavity 122 and the cavity 422, respectively), microprocessor 502 may also define one or more channels 524. For example, the microprocessor 502 may define the channels 524 along a surface of the microprocessor 502, such as a top surface 528 of the microprocessor 502. As discussed further below, the channels 524 may guide a fluid (e.g., a coolant fluid) along the top surface 528 of the microprocessor 502 to thermally regulate the microprocessor 502.

The channels 524 defined by the microprocessor 502 may be formed in any desired manner. For example, in some implementations, the microprocessor 502 may include or may be substantially made of a material, such as silicon. In such a case, the top surface 528 of the microprocessor 502 may be etched or otherwise manufactured (e.g., cut, notched, laser-cut, molded, extruded, pultruded, etc.) to form the channels 524 therein that may be separated by walls 530 located between the channels 524. That is, the channels 524 may be grooves formed in the microprocessor 502. As such, the channels 524 may be integrally formed with the microprocessor 502.

The channels 524 shown in FIGS. 5 and 6 may have any geometry, cross-section, or shape. For example, the channels 524 may have any desired cross-section shaped. The cross-sectional shape may be substantially U-shaped, V-shaped, J-shaped, C-shaped, D-shaped, or a combination thereof. Additionally, the microprocessor 502 (e.g., the top surface 528 of the microprocessor 502) may define any number of the channels 524 (e.g., one or more, two or more, three or more, five or more, ten or more, fifty or more, one hundred or more, etc.). For example, the microprocessor 502 may include of define micro-channels similar to those described in U.S. 8,474,516, all of which is incorporated herein in its entirety for all purposes. Such micro-channels may be interconnected such that a fluid may flow between the channels 524 to effectively cool the microprocessor 502. The micro-channels may extend or wind in any desired manner to effectively dissipate the heat generated by the microprocessor 502 using a fluid (e.g., using a coolant fluid).

While it is envisioned that the channels 524 may be integrated into the top surface 528 of the microprocessor 502, such as via etching of the top surface 528, the channels 524 may also be defined in other ways. By way of example, as shown in FIG. 6, the walls 530 separating the channels 524 defined by the microprocessor 502 may, in some implementations, be fins that extend from (e.g., project from) the top surface 528 of the microprocessor 502. That is, the fins may be integrally (i.e., monolithically) formed with the microprocessor 502 or the fins may be coupled to the top surface 528 of the microprocessor 502, such as via an adhesive or other manner of bonding. Thus, the channels 524 defined by the microprocessor 502 may be formed in a number of ways to effectively thermally regulate the microprocessor 502.

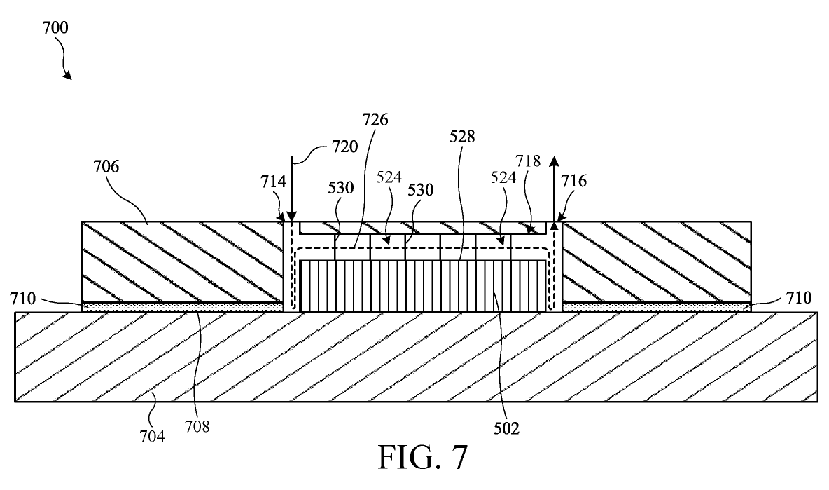

FIG. 7 illustrates another example of a microprocessor assembly 700. The microprocessor assembly 700 may be similar to the microprocessor assembly 100 shown in FIGS. 1-3 and/or the microprocessor assembly 400 shown in FIG. 4. For example, the microprocessor assembly 700 may be configured to thermally regulate a microprocessor, such as the microprocessor 502 shown in FIGS. 5 and 6. The microprocessor assembly 700 may provide an alternative means of thermally regulating the microprocessor 502 compared to the thermal regulation accomplished by the microprocessor assembly 100 and/or the microprocessor assembly 400.

The microprocessor assembly 700 may also include the microprocessor 502, a PCB 704, and a manifold 706. The microprocessor 502 may be disposed on (e.g., coupled to) a top surface 708 of the PCB 704. Similarly, the manifold 706 may be coupled to the top surface 708 of the PCB 704, such as via an adhesive 710. The PCB 704 may be similar to the PCB 104 of the microprocessor assembly 100 and/or the PCB 404 of the microprocessor assembly 400.

Similar to the manifold 106 of the microprocessor assembly 100 and the manifold 406 of the microprocessor assembly 400, the manifold 706 may be configured to thermally regulate the microprocessor 502. For example, the manifold 706 may be in direct and/or indirect thermal communication with the microprocessor 502. By way of example, the microprocessor 502 may be in direct communication with the manifold 706, whereby at least a portion of the walls 530 of the microprocessor 502 may directly contact the manifold 706. That is, the microprocessor 502 may be configured to transfer heat generated by the microprocessor 502 directly to the manifold 706 to dissipate the heat. For example, the manifold 706 may be coupled to the top surface 708 of the PCB 704 and may define a void 718 to substantially or entirely enclose the microprocessor 502 between the manifold 706 and the PCB 704.

In some configurations, the microprocessor 502 (e.g., the walls 530 of the microprocessor 502 that at least partially define the channels 524 of the microprocessor 502) may be spaced apart from the manifold 706. For example, a gap (e.g., an air gap or other fluid gap) may exist between the walls 530 of the microprocessor 502 and the manifold 706 within the void 718.

Also similar to the manifold 106 of the microprocessor assembly 100 and the manifold 406 of the microprocessor assembly 400, the manifold 706 may be configured to thermally regulate the microprocessor 502 via fluid control. That is, the manifold 706 may include an inlet port 714 and an outlet port 716. The inlet port 714 and/or the outlet port 716 may be in fluid communication with one another via the void 718. That is, a fluid 720 may travel through the void 718 defined between the manifold 706 and the top surface 708 of the PCB 704 between the inlet port 714 and the outlet port 716. For example, the inlet port 714 and the outlet port 716 may extend through the manifold 706 from an outer surface or outer surfaces of the manifold 706 into the void 718. The fluid 720 may thus enter the void 718 through the inlet port 714, travel through the void 718 to thermally regulate the microprocessor 502, and exit the void 718 through the outlet port 716.

The inlet port 714 and the outlet port 716 may be located on a top side of the manifold 706. Based on the location of the inlet port 714 and the outlet port 716, the fluid 720 may enter the manifold 706 at the top side of the manifold 706 via the inlet port 714, travel through the void 718, and exit the void 718 at the top side of the manifold 706 via the outlet port 716.

As discussed above, to more effectively thermally regulate the microprocessor 502, the microprocessor 502 may define the channels 524. Based on the positioning of the microprocessor 502 within the void 718, the channels 524 defined by the microprocessor 502 may also be located within the void 718. The channels 524 may at least partially define a flow path 726 of the fluid 720 through the void 718. For example, the channels 524 may be interconnected winding micro-channels, whereby the micro-channels may route the fluid 720 along the flow path 726 so that the fluid 720 may travel along the flow path 726 along the top surface 528 of the microprocessor 502. By way of example, the fluid 720 may enter the void 718 through the inlet port 714, flow along the flow path 726 through at least a portion of the channels 524 and along the top surface 528 of the microprocessor 502 to thermally regulate the microprocessor 502, and exit the void 718 – and thus also exit the manifold 706 – through the outlet port 716 to thereby transfer the heat generated by the microprocessor 502 out of the manifold 706.

As shown in FIG. 7, the adhesive 710 may form a seal between the manifold 706 and the PCB 704 such that the fluid 720 may flow (e.g., along the flow path 726) along opposing side edges of the microprocessor 502 and along the top surface 528 of the microprocessor 502 to effectively thermally regulate the microprocessor 502. In some configurations, in addition to, or in lieu of, the adhesive 710, a potting material may be implemented to bond the manifold 706 to the PCB 704 and form a seal therebetween. Thus, the adhesive 710 and/or the potting material may provide a seal that allows the fluid 720 to flow through the void 718 without unwanted leakage between the manifold 706 and the PCB 704.

Based on the structure of the microprocessor assembly 700, the manifold 706 may, in some implementations, be free of any channels integrated into the manifold 706. Instead, the channels 524 defined by the microprocessor 502 may direct and receive the fluid 720 to thermally regulate the microprocessor 502. To facilitate flow of the fluid 720 through the channels 524 of the microprocessor 502, the manifold 706 and/or the PCB 704 may be configured to fluidically seal the microprocessor 502 within the void 718 between the manifold 706 and the PCB 704. Thus, the fluid 720 may be directed through the channels 524, such as along the flow path 726, to thermally regulate the microprocessor 502.

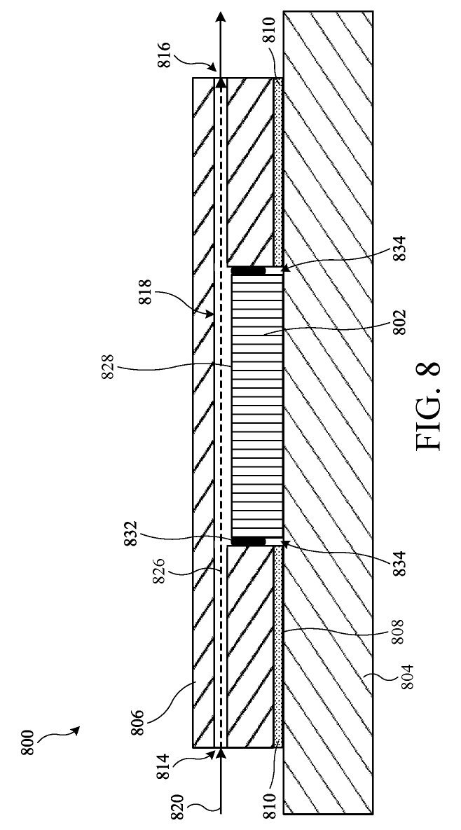

FIG. 8 illustrates another example of a microprocessor assembly 800. The microprocessor assembly 800 may be similar to the microprocessor assembly 700 shown in FIG. 7. For example, the microprocessor assembly 800 may be configured to thermally regulate a microprocessor, such as the microprocessor 802. The microprocessor assembly 800 may provide similar thermal regulation when compared to the microprocessor assembly 700, which may provide an alternative means of thermally regulating the microprocessor 802 compared to the thermal regulation accomplished by the microprocessor assembly 100 and/or the microprocessor assembly 400.

The microprocessor assembly 800 may include the microprocessor 802, a PCB 804, and a manifold 806. The microprocessor 802 may be disposed on (e.g., coupled to) a top surface 808 of the PCB 804. Similarly, the manifold 806 may be coupled to the top surface 808 of the PCB 804, such as via an adhesive 810 or potting material. The PCB 804 may be similar to the PCB 704 of the microprocessor assembly 700.

Similar to the manifold 706 of the microprocessor assembly 700, the manifold 806 may be configured to thermally regulate the microprocessor 802. For example, the manifold 806 may be in indirect thermal communication with the microprocessor 802. By way of example, the microprocessor 802 may be in indirect communication with the manifold via a fluid 820 flowing through a void 818 defined by the manifold 806, whereby the void 818 may substantially or entirely enclose the microprocessor 802 between the manifold 806 and the PCB 804.

As discussed above, the microprocessor assembly 800 may be configured to thermally regulate the microprocessor 802 via fluid control. That is, the manifold 806 may include an inlet port 814 and an outlet port 816. The inlet port 814 and/or the outlet port 816 may be in fluid communication with one another via the void 818. That is, the fluid 820 may travel through the void 818 defined between the manifold 806 and the top surface 808 of the PCB 804 between the inlet port 814 and the outlet port 816. For example, the fluid 820 may enter the void 818 through the inlet port 814, travel through the void 818 to thermally regulate the microprocessor 802, and exit the void 818 through the outlet port 816.

To better direct the fluid 820 through the void 818, a seal 832 may be disposed within the void 818 between the microprocessor 802 and the manifold 806. For example, the seal 832 may be positioned within one or more gaps 834 that may exist between the microprocessor 802 and the manifold 806 to provide a fluid seal for the fluid 820, thereby preventing the fluid 820 from penetrating the gaps 834 between the microprocessor 802 and the manifold 806. Thus, the seal 832 may also help direct the fluid 820 along the top surface 828 of the microprocessor 802 while preventing the fluid 820 from flowing along opposing side edges of the microprocessor 802.

The seal 832 may be any type of seal, such as a gasket, O-ring, foam, compressible member, or other type of seal that may fluidically seal the gaps 834 that may exist between the microprocessor 802 and the manifold 806 to prevent penetration of the fluid 820 into the gaps 834. In some implementations, the microprocessor assembly 800 may include more than one seal. For example, the microprocessor assembly 800 may include a plurality of seals that may be similar to the seal 832 to fluidically seal the gaps 834 that may exist between the microprocessor 802 and the manifold 806, between the manifold 806 and the PCB 804, or both.

Based on the above configuration, and as shown in FIG. 8, the fluid 820 may enter the void 818 through the inlet port 814, flow along the flow path 826 so that the fluid 820 may flow substantially along the top surface 828 of the microprocessor 802 to thermally regulate the microprocessor 802, and exit the void 818 – and thus also exit the manifold 806 – through the outlet port 816 to thereby transfer the head generated by the microprocessor 802 out of the manifold 806.

### Illustrative Embodiments

The implementations of this disclosure include a microprocessor assembly. The microprocessor assembly includes a printed circuit board (PCB), a microprocessor coupled to the PCB, and a manifold coupled to the PCB and at least partially surrounding the microprocessor. The manifold defines one or more channels that are configured to receive fluid flow through at least a portion of the one or more channels to thermally regulate the microprocessor.

In some implementations, the manifold includes an inlet port and an outlet port. A fluid is configured to enter the one or more channels through the inlet port and exit the one or more channels through the outlet port.

In some implementations, the manifold defines a cavity and the one or more channels are located within the cavity.

In some implementations, the cavity is enclosed by the manifold such that the fluid is only able to enter or exit the one or more channels through the inlet port, the outlet port, or both.

In some implementations, the manifold and the PCB define a void therebetween, and the microprocessor is located within the void.

In some implementations, the microprocessor assembly further comprises a thermal interface material that is positioned between the microprocessor and the manifold, and the thermal interface material is located in the void.

In some implementations, the microprocessor is in indirect contact with the manifold via the thermal interface material.

In some implementations, heat generated by the microprocessor is configured to transfer from the microprocessor to the thermal interface material, and then further transfer from the thermal interface material to the manifold to thermally regulate the microprocessor.

In some implementations, the microprocessor and the manifold are coupled to a top surface of the PCB.

In some implementations, the one or more channels of the manifold are winding micro-channels that define a flow path of the fluid flow.

The implementations of this disclosure also include a manifold configured to thermally regulate a microprocessor in thermal communication with the manifold. The manifold comprises a cavity defined by the manifold and configured to contain the microprocessor, an inlet port that is configured to regulate fluid flow entering the cavity, an outlet port that is configured to regulate fluid flow exiting the cavity, and one or more channels defined by the manifold and located within the cavity. To thermally regulate the microprocessor, at least a portion of the one or more channels are configured to receive the fluid flow therein.

In some implementations, the manifold is configured to indirectly contact the microprocessor.

In some implementations, the inlet port and the outlet port are located along an upper surface of the manifold.

In some implementations, the inlet port and the outlet port are located on opposing sides of the manifold.

In some implementations, the manifold is configured to be coupled to a printed circuit board (PCB) via an adhesive such that the microprocessor is located between the manifold and the PCB, and the microprocessor is contained within a void defined by the manifold and the PCB.

In some implementations, the manifold is configured to be coupled to a top surface of the PCB via the adhesive.

The implementations of this disclosure also include a microprocessor assembly. The microprocessor assembly includes a printed circuit board (PCB), a microprocessor coupled to the PCB, wherein the microprocessor defines one or more channels along a surface of the microprocessor, and a manifold coupled to the PCB. The manifold and the PCB define a void therebetween. The microprocessor is located in the void. The one or more channels are configured to receive fluid flow through at least a portion of the one or more channels to thermally regulate the microprocessor.

In some implementations, the one or more channels are etched into a top surface of the microprocessor.

In some implementations, the microprocessor assembly further comprises a seal disposed between the microprocessor and the manifold and located within the void. The seal is configured to prevent the fluid flow from penetrating a gap between the microprocessor and the manifold.

In some implementations, the one or more channels are winding micro-channels that define a flow path of the fluid flow.

While the disclosure has been described in connection with certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures as is permitted under the law.

Persons skilled in the art will understand that the various embodiments of the present disclosure and shown in the accompanying figures constitute non-limiting examples, and that additional components and features may be added to any of the embodiments discussed hereinabove without departing from the scope of the present disclosure. Additionally, persons skilled in the art will understand that the elements and features shown or described in connection with one embodiment may be combined with those of another embodiment without departing from the scope of the present disclosure to achieve any desired result and will appreciate further features and advantages of the presently disclosed subject matter based on the description provided. Variations, combinations, and/or modifications to any of the embodiments and/or features of the embodiments described herein that are within the abilities of a person having ordinary skill in the art are also within the scope of the present disclosure, as are alternative embodiments that may result from combining, integrating, and/or omitting features from any of the disclosed embodiments.

Use of the term “optionally” with respect to any element of a claim means that the element may be included or omitted, with both alternatives being within the scope of the claim. Additionally, use of broader terms such as “comprises,” “includes,” and “having” should be understood to provide support for narrower terms such as “consisting of,” “consisting essentially of,” and “comprised substantially of.” Accordingly, the scope of protection is not limited by the description set out above, but is defined by the claims that follow, and includes all equivalents of the subject matter of the claims.

In the preceding description, reference may be made to the spatial relationship between the various structures illustrated in the accompanying drawings, and to the spatial orientation of the structures. However, as will be recognized by those skilled in the art after a complete reading of this disclosure, the structures described herein may be positioned and oriented in any manner suitable for their intended purpose. Thus, the use of terms such as “above,” “below,” “upper,” “lower,” “inner,” “outer,” “left,” “right,” “upward,” “downward,” “inward,” “outward,” “horizontal,” “vertical,” etc., should be understood to describe a relative relationship between the structures and/or a spatial orientation of the structures. Those skilled in the art will also recognize that the use of such terms may be provided in the context of the illustrations provided by the corresponding figure(s).

Additionally, terms such as “approximately,” “generally,” “substantially,” and the like should be understood to allow for variations in any numerical range or concept with which they are associated and encompass variations on the order of 25% (e.g., to allow for manufacturing tolerances and/or deviations in design). For example, the term “generally parallel” should be understood as referring to configurations in with the pertinent components are oriented so as to define an angle therebetween that is equal to 180° ± 25% (e.g., an angle that lies within the range of (approximately) 135° to (approximately) 225°). The term “generally parallel” should thus be understood as referring to encompass configurations in which the pertinent components are arranged in parallel relation.

Although terms such as “first,” “second,” “third,” etc., may be used herein to describe various operations, elements, components, regions, and/or sections, these operations, elements, components, regions, and/or sections should not be limited by the use of these terms in that these terms are used to distinguish one operation, element, component, region, or section from another. Thus, unless expressly stated otherwise, a first operation, element, component, region, or section could be termed a second operation, element, component, region, or section without departing from the scope of the present disclosure.

Each and every claim is incorporated as further disclosure into the specification and represents embodiments of the present disclosure. Also, the phrases “at least one of A, B, and C” and “A and/or B and/or C” should each be interpreted to include only A, only B, only C, or any combination of A, B, and C.

What is claimed is:

1. A microprocessor assembly, comprising:
a printed circuit board (PCB);
a microprocessor coupled to the PCB; and
a manifold coupled to the PCB and at least partially surrounding the microprocessor, wherein the manifold defines one or more channels configured to receive fluid flow through at least a portion of the one or more channels to thermally regulate the microprocessor.

2. The microprocessor assembly of claim 1, wherein the manifold includes an inlet port and an outlet port, a fluid is configured to enter the one or more channels through the inlet port, and the fluid is configured to exit the one or more channels through the outlet port.

3. The microprocessor assembly of claim 2, wherein the manifold defines a cavity and the one or more channels are located within the cavity.

4. The microprocessor assembly of claim 3, wherein the cavity is enclosed by the manifold such that the fluid is only able to enter or exit the one or more channels through the inlet port, the outlet port, or both.

5. The microprocessor assembly of claim 1, wherein the manifold and the PCB define a void therebetween, and wherein the microprocessor is located within the void.

6. The microprocessor assembly of claim 5, further comprising:
a thermal interface material that is positioned between the microprocessor and the manifold, wherein the thermal interface material is located in the void.

7. The microprocessor assembly of claim 6, wherein the microprocessor is in indirect contact with the manifold via the thermal interface material.

8. The microprocessor assembly of claim 7, wherein heat generated by the microprocessor is configured to transfer from the microprocessor to the thermal interface material, and then further transfer from the thermal interface material to the manifold to thermally regulate the microprocessor.

9. The microprocessor assembly of claim 1, wherein the microprocessor and the manifold are coupled to a top surface of the PCB.

10. The microprocessor assembly of claim 1, wherein the one or more channels of the manifold are winding micro-channels that define a flow path of the fluid flow.

11. A manifold configured to thermally regulate a microprocessor in thermal communication with the manifold, comprising:
a cavity defined by the manifold and configured to contain the microprocessor;
an inlet port that is configured to regulate fluid flow entering the cavity;
an outlet port that is configured to regulate the fluid flow exiting the cavity; and
one or more channels defined by the manifold and located within the cavity,
wherein to thermally regulate the microprocessor, at least a portion of the one or more channels are configured to receive the fluid flow therein.

12. The manifold of claim 11, wherein the manifold is configured to indirectly contact the microprocessor.

13. The manifold of claim 11, wherein the inlet port and the outlet port are located along an upper surface of the manifold.

14. The manifold of claim 11, wherein the inlet port and the outlet port are located on opposing sides of the manifold.

15. The manifold of claim 11, wherein the manifold is configured to be coupled to a printed circuit board (PCB) via an adhesive such that the microprocessor is located between the manifold and the PCB, and the microprocessor is contained within a void defined by the manifold and the PCB.

16. The manifold of claim 15, wherein the manifold is configured to be coupled to a top surface of the PCB via the adhesive.

17. A microprocessor assembly, comprising:
a printed circuit board (PCB);
a microprocessor coupled to the PCB, wherein the microprocessor defines one or more channels along a surface of the microprocessor; and
a manifold coupled to the PCB, wherein the manifold and the PCB define a void therebetween, the microprocessor is located in the void, and the one or more channels are configured to receive fluid flow through at least a portion of the one or more channels to thermally regulate the microprocessor.

18. The microprocessor of claim 17, wherein the one or more channels are etched into a top surface of the microprocessor.

19. The microprocessor of claim 17, further comprising a seal disposed between the microprocessor and the manifold and located within the void, wherein the seal is configured to prevent the fluid flow from penetrating a gap between the microprocessor and the manifold.

20. The microprocessor of claim 17, wherein the one or more channels are winding micro-channels that define a flow path of the fluid flow.
